(19) United States
(12) Patent Application Publication
(10) Pub. No.: US 2018/0074397 A1
(43) Pub. Date: Mar. 15, 2018

(54) CHEMICALLY STRENGTHENED GLASS

(71) Applicant: ASAHI GLASS COMPANY, LIMITED, Tokyo (JP)

(72) Inventors: Akio KOIKE, Tokyo (JP); Haruhiko ISHIMOTO, Tokyo (JP); Tatsuya IWASAKI, Tokyo (JP); Junichi KAKUTA, Tokyo (JP)

(73) Assignee: ASAHI GLASS COMPANY, LIMITED, Tokyo (JP)

(21) Appl. No.: 15/822,314

(22) Filed: Nov. 27, 2017

Related U.S. Application Data
(63) Continuation of application No. PCT/JP2016/065647, filed on May 26, 2016.

(30) Foreign Application Priority Data
May 29, 2015 (JP) 2015-110899

(51) Int. Cl. G03F 1/60; C03C 3/087; C03C 4/18; C03C 21/00; G01N 3/20

(52) U.S. Cl. CPC G03F 1/60; C03C 3/087; C03C 4/18; C03C 21/002; G01N 2203/0003; C03C 2204/00; G01N 2203/0023; G01N 2203/0064; G01N 3/20

(57) ABSTRACT

A chemically strengthened glass includes a first main surface, a second main surface opposite to the first main surface, and an end surface connecting the first main surface and the second main surface. A compressive stress layer is provided in the first main surface and the second main surface. An average sheet thickness t is from 0.06 to 0.25 mm. When a bending test method is performed, a crack originating in at least one main surface of the first main surface and the second main surface is not formed.

### TECHNICAL FIELD

The present invention relates to a chemically strengthened glass, more specifically, a chemically strengthened glass with excellent flexibility.

### BACKGROUND ART

Conventionally, as a material of a photomask substrate, an LCD image mask substrate, etc., a polymer film such as PET capable of responding to a roll-to-roll process has been used so as to raise the throughput. However, a polymer film undergoes a dimensional change due to temperature or humidity.

As another material of a photomask substrate, an LCD image mask substrate, etc., for example, silica glass that is resistant to a dimensional change due to temperature or humidity is also used (see, Patent Document 1).

An alkali-free glass having a sheet thickness of from 1 to 200 μm is known as a glass film capable of withstanding bending (see, Patent Document 2).

### RELATED ART

### Patent Document

Patent Document 1: JP-A-2007-182367

Patent Document 2: International Publication No. 2010/038757

### SUMMARY OF THE INVENTION

### Problems that the Invention is to Solve

However, silica glass, etc. described in Patent Document 1 is generally brittle and readily broken when bent and therefore, cannot be used for a roll-to-roll process.

The alkali-free glass having a small sheet thickness described in Patent Document 2 can withstand bending with a large radius of curvature but is relatively easily broken when it is bent to a small radius of curvature or a stress is applied to the glass surface during handling.

The present invention has been made taking into account the above-described problems and aims at providing a flexible and high-strength glass.

### Means for Solving the Problems

As a result of intensive studies in consideration of those conventional problems, the present inventor has found that the problems can be solved by the following chemically strengthened glass. The present invention has been accomplished based on this finding.

That is, the chemically strengthened glass of the present invention is a chemically strengthened glass including a first main surface, a second main surface opposite to the first main surface, and an end surface connecting the first main surface and the second main surface, wherein a compressive stress layer is provided in the first main surface and the second main surface, an average sheet thickness t is from 0.06 to 0.25 mm, and when the following bending test method is performed, a crack originating in at least one main surface of the first main surface and the second main surface is not formed.

### (Bending Test Method)

A bending test method of disposing a first support board and a second support board in parallel so that a supporting surface of the first support board and a supporting surface of the second support board are opposed to each other,

arranging an end part of the chemically strengthened glass to be supported respectively by the first support board and the second support board,

while maintaining a distance between the supporting surface of the first support board and the supporting surface of the second support board at a distance D [mm] determined according to the following formula (1), displacing a position of the second support board relative to the first support board by 200 mm in a direction that is parallel to the supporting surface of the first support board and the supporting surface of the second support board and that does not change a curvature direction of the chemically strengthened glass, and

examining whether a crack is formed or not in the chemically strengthened glass curved between the first support board and the second support board, is performed.

D=(A×E×t/σ)+t (1)

D; the distance between the supporting surface of the first support board and the supporting surface of the second support board (unit [mm])

A=1.198

E; Young's modulus of the chemically strengthened glass (unit [MPa])

T; the average sheet thickness of the chemically strengthened glass (unit [mm])

σ=200 (unit [MPa])

### Advantage of the Invention

In the chemically strengthened glass of the present invention, the strength is enhanced by chemical strengthening. The average sheet thickness is small and a crack is not formed in the bending test method above, thus, the flexibility is excellent. That is, according to the present invention, a flexible and high-strength glass is provided.

### BRIEF DESCRIPTION OF THE DRAWINGS

FIG. 1 is a diagram illustrating the bending test method in the present invention.

FIG. 2 is a cross-sectional view of the chemically strengthened glass according to one embodiment of the present invention.

FIG. 3 is a diagram illustrating how to perform chamfering for manufacturing the glass according to one embodiment of the present invention.

FIG. 4 is a cross-sectional view of the chemically strengthened glass according to one embodiment of the present invention.

FIG. 5 is a cross-sectional view of the chemically strengthened glass according to one embodiment of the present invention.

### MODE FOR CARRYING OUT THE INVENTION

The embodiments of the present invention are described in detail below.

The chemically strengthened glass according to one embodiment of the present invention is a chemically strengthened glass including a first main surface, a second main surface opposite to the first main surface, and an end surface connecting the first main surface and the second main surface, wherein a compressive stress layer is provided in the first main surface and the second main surface, an average sheet thickness t is from 0.06 to 0.25 mm, and when the following bending test method is performed, a crack originating in at least one main surface of the first main surface and the second main surface is not formed.

### (Bending Test Method)

A bending test method of disposing a first support board and a second support board in parallel so that a supporting surface of the first support board and a supporting surface of the second support board are opposed to each other,

arranging an end part of the chemically strengthened glass to be supported respectively by the first support board and the second support board,

while maintaining a distance between the supporting surface of the first support board and the supporting surface of the second support board at a distance D [mm] determined according to the following formula (1), displacing a position of the second support board relative to the first support board by 200 mm in a direction that is parallel to the supporting surface of the first support board and the supporting surface of the second support board and that does not change a curvature direction of the chemically strengthened glass, and

examining whether a crack is formed or not in the chemically strengthened glass curved between the first support board and the second support board, is performed.

D=(A×E×t/σ)+t (1)

D; the distance between the supporting surface of the first support board and the supporting surface of the second support board (unit [mm])

A=1.198

E; Young's modulus of the chemically strengthened glass (unit [MPa])

T; the average sheet thickness of the chemically strengthened glass (unit [mm])

σ=200 (unit [MPa])

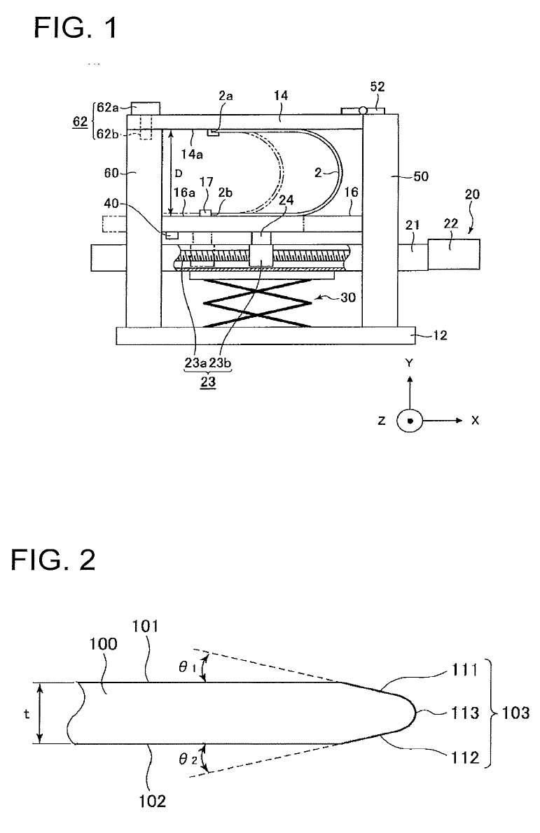

In the following, the bending test method of this embodiment is described by referring to FIG. 1. First, the bending test apparatus used for the bending test method in this embodiment is described.

The bending test apparatus 10 is a device for curving the chemically strengthened glass 2 of this embodiment. The durability of the chemically strengthened glass 2 is determined by examining whether a crack is formed or not in the chemically strengthened glass 2 which is curved.

As illustrated in FIG. 1, the bending test apparatus 10 includes a base 12, a first support board (upper-side support board) 14, a second support board (lower-side support board) 16, a displacement unit 20, an adjustment unit 30, a detection unit 40, a support unit 50, and a placement unit 60.

The first support board 14 supports an end part 2a of the chemically strengthened glass 2. A supporting surface 14a of the first support board 14 is a downfacing flat surface and is a surface to which the end part 2a of the chemically strengthened glass 2 is fixed.

The second support board 16 supports an end part 2b of the chemically strengthened glass 2, similarly to the first support board 14. A supporting surface 16a of the second support board 16 is an upfacing flat surface and is a placement surface on which the end part 2b of the chemically strengthened glass 2 is placed. The first support board 14 and the second support board 16 are disposed in parallel such that the supporting surface 14a of the first support board 14 and the supporting surface 16a of the second support board 16 are opposed to each other. Another end part of the chemically strengthened glass 2 is pressed against the supporting surface 16a of the second support 16 by gravity and fixed thereto by frictional force. On the supporting surface 16a of the second support board 16, a stopper 17 abutting the end part 2b of the chemically strengthened glass 2 is provided so as to prevent positional deviation of the chemically strengthened glass 2.

The displacement unit 20 displaces the position of the second support board 16 relative to the first support board 14 while maintaining the distance D between the supporting surface 14a of the first support board 14 and the supporting surface 16a of the second support board 16, which are parallel to each other. For displacing the position of the second support board 16 relative to the first support board 14, the displacement unit 20 displaces the second support board 16 in the direction that is parallel to the base 12 and that does not change the curvature direction of the chemically strengthened glass 2. Here, the curvature direction of the chemically strengthened glass 2 in FIG. 1 is an arrow X direction. When the second support board 16 is moved in an arrow Z direction (in FIG. 1, a direction perpendicular to the plane of paper) relative to the base 12, the curvature direction of the chemically strengthened glass 2 varies and therefore, the bending test cannot be performed accurately.

The displacement unit 20 displaces the second support board 16 in parallel to the base 12 but may move the first support board 14 in parallel to the base 12 or may move both the first support board 14 and the second support board 16 in parallel. In either case, the position of the second support board 16 relative to the first support board 14 is displaced.

The displacement unit 20 is composed of an ascending-descending frame 21, a motor 22, a ball screw mechanism 23, a slider block 24, etc. The ascending-descending frame 21 is movable relative to the base 12. The motor 22 is attached to the ascending-descending frame 21. The ball screw mechanism 23 converts rotary motion of the motor 22 to linear motion and transmits the motion to the slider block 24. The slider block 24 is connected to the second support board 16 and moves together with the second support board 16 in parallel to the base 12. The motor 22 rotates the ball screw 23a under the control of a controller composed of a microcomputer, etc. and displaces a ball screw nut 23b. As the ball screw nut 23b moves, the slider block 24 and the second support board 16 are displaced in parallel to the base 12.

The adjustment unit 30 adjusts the distance D between the supporting surface 14a of the first support board 14 and the supporting surface 16a of the second support board 16, which are parallel to each other. The adjustment unit 30 is composed of, for example, a pantograph jack.

The detection unit 40 is composed of a sensor (for example, AE sensor) detecting an elastic wave (for example, AE (Acoustic Emission) wave) generated when a crack is formed in the chemically strengthened glass 2. Whether a crack is formed or not in the chemically strengthened glass 2 is known in the state of the glass being supported by the first support board 14 and the second support board 16. A crack of the chemically strengthened glass 2 is formed originating from a defect (e.g., scratch, deposit, inclusion) present in the chemically strengthened glass 2. In the bending test apparatus 10 of this embodiment, the detection unit 40 is attached to the second support board 16 supporting the chemically strengthened glass 2, but it may be attached to the first support board 14.

The support unit 50 is fixed to the base 12 and rotatably supports the first support board 14 via a coupling unit 52 such as a hinge. The first support board 14 is freely rotated between a test position (first position) where the supporting surface 14a of the first support board 14 is parallel to the supporting surface 16a of the second support board 16, and a set position (second position) where the supporting surface 14a of the first support board 14 inclines relative to the supporting surface 16a of the second support board 16. In the course of rotating the first support board 14 from the test position to the set position, a radius of curvature of a curvature part of the chemically strengthened glass supported by the first support board 14 and the second support board 16 gradually increases.

The placement unit 60 is fixed to the base 12 and carries the first support board 14 arranged on the upper side than the second support board 16. When the first support board 14 is located at the test position (the position in FIG. 1), it is placed on an upper end surface of the placement unit 60. The first support board 14 may be placed on a plurality of placement units 60 so as to stabilize the posture of the first support board 14. In each placement unit 60, a bolt hole for threadedly engaging a shaft part 62b of a bolt 62 is formed. In the first support board 14, a through hole for allowing the shaft part 62b of the bolt 62 to pass therethrough is formed. The first support board 14 is put between a head 62a of the bolt 62 and each placement unit 60, and the posture of the first support board 14 can thereby be stabilized.

The bending test method in this embodiment is described below.

In this embodiment, a bending test method of disposing a first support board 14 and a second support board 16 in parallel so that the supporting surface 14a of the first support board 14 and the supporting surface 16b of the second support board 16 are opposed to each other,

arranging an end part 2a and an end part 2b of the chemically strengthened glass 2 to be supported respectively by the first support board 14 and the second support board 16,

while maintaining the distance D between the supporting surface 14a of the first support board 14 and the supporting surface 16a of the second support board 16 at a distance D [mm] determined according to the following formula (1), displacing the position of the second support board 16 relative to the first support board 14 by 200 mm in the direction that is parallel to the supporting surface 14a of the first support board 14 and the supporting surface 16a of the second support board 16 and that does not change the curvature direction of the chemically strengthened glass 2, and

examining whether a crack is formed or not in the chemically strengthened glass 2 caused to form a curvature between the first support board 14 and the second support board 16, is performed:

D=(A×E×t/σ)+t (1)

D: the distance between the supporting surface 14a of the first support board 14 and the supporting surface 16a of the second support board 16 (unit: [mm])

A=1.198 (constant specific to this test)

E: the Young's modulus of the chemically strengthened glass 2 (unit: [MPa])

t: the average sheet thickness of the chemically strengthened glass 2 (unit: [mm])

σ=200 (unit: [MPa])

First, an operator arranges end parts 2a and 2b of the chemically strengthened glass 2 to be supported respectively by the first support board 14 and the second support board 16. Next, the operator manually actuates the adjustment unit 30, and the distance D between the supporting surface 14a of the first support board 14 and the supporting surface 16a of the second support board 16, which are parallel to each other, is adjusted according to formula (1) so that the chemically strengthened glass 2 is curved between the first support board 14 and the second support board 16 and thereby produce, in the chemically strengthened glass 2, a tensile stress (σ=200 MPa) working out to a threshold value. Here, the tensile stress (σ=200 MPa) working out to a threshold value is generated on an outer side of the curvature part of the chemically strengthened glass 2, i.e., generated when the main surface in contact with the support board reaches the curvature part (in FIG. 1, a right edge of the chemically strengthened glass 2) due to the later-described movement.

Subsequently, the operator actuates the displacement unit 20 under the control of a controller and while maintaining the distance D, the position of the second support board 16 relative to the first support board 14 is displaced 200 mm in the direction that is parallel to the supporting surface 14a of the first support board 14 and the supporting surface 16a of the second support board 16 and that does not change the curvature direction of the chemically strengthened glass 2. The position where a tensile stress σ of the chemically strengthened glass 2 is generated can thereby be moved.

Whether a crack is formed or not in the chemically strengthened glass 2 caused to form a curvature between the first support board 14 and the second support board 16 can be examined by detecting the presence or absence of an elastic wave produced when a crack is formed, by means of the detection unit 40. Whether a crack is formed or not in the chemically strengthened glass 2 can be confirmed in the state of the glass being supported by the first support board 14 and the second support board 16. Whether a crack is formed or not in the chemically strengthened glass 2 can also be confirmed by whether a scratch having a length of 10 mm or more is produced or not in either the first main surface or the second main surface of the chemically strengthened glass 2.

In this embodiment, in order to confirm that a breaking strength of the chemically strengthened glass 2 is larger than the threshold value (200 MPa), whether a crack is formed or not is examined by performing the test with a distance D corresponding to the threshold value (200 MPa). In the case where a crack is not formed, the braking strength of the chemically strengthened glass 2 can be regarded as being larger than the threshold value (200 MPa).

Usually, the strength is likely to be lower in an edge part than in a central part of the main surface of chemically strengthened glass due to the effect of processing variation, etc., and when the bending test is conducted, a crack originating in an end surface is often generated. In particular, although no problem arises with a small region, in the case of a large region, for example, a region where the moving distance is 200 mm as in this embodiment, a crack originating in the end surface is readily generated. The chemically strengthened glass of this embodiment is preferably a chemically strengthened glass where when the above-described bending test method is performed, a crack originating in the end surface connecting the first main surface and the second main surface is not formed.

The chemically strengthened glass of this embodiment is a chemically strengthened glass where when the above-described bending test method is performed, a crack originating in at least one main surface of the first main surface and the second main surface facing the first main surface is not formed. The chemically strengthened glass is more preferably a chemically strengthened glass where when the above-described bending test method is performed, neither a crack originating in the first main surface nor a crack originating in the second main surface are formed. In order to examine that neither a crack originating in the first main surface nor a crack originating in the second main surface are formed, after performing the above-described testing method such that either one main surface abuts the first support board 14 and the second support board 16, the above-described bending test method may be performed by reversing the main surface and abutting the other main surface against the first support board 14 and the second support board 16. The “crack originating in a certain surface” as used in the present description means a crack originating at a certain position in a certain surface.

The chemically strengthened glass of this embodiment is a chemically strengthened glass where when the above-described bending test method is performed, a crack originating in at least one main surface of the first main surface and the second main surface is not formed. Accordingly, the breaking strength by the above-described bending test method is larger than 200 MPa, and the glass is a flexible glass with excellent flexibility.

The breaking strength of the chemically strengthened glass 2 can be examined as follows.

First, an operator disposes support boards in parallel so that the supporting surface 14a of the first support board 14 and the supporting surface 16b of the second support board 16 are opposed to each other, and arranges end parts 2a and 2b of the chemically strengthened glass 2 to be supported respectively by the first support board 14 and the second support board 16. Next, the operator manually actuates the adjustment unit 30, and the distance D between the supporting surface 14a of the first support board 14 and the supporting surface 16a of the second support board 16, which are parallel to each other, is adjusted to produce a tensile stress of the set value in the chemically strengthened glass 2 caused to form a curvature between the first support board 14 and the second support board 16.

The tensile stress σ generated at an apex of the curvature part of the chemically strengthened glass 2 (in FIG. 1, the right edge of the chemically strengthened glass 2) can be calculated based on the following formula (2).

σ=(A×E×t)/(D−t) (2)

D: the distance between the supporting surface of the first support board and the supporting surface of the second support board (unit: [mm])

A=1.198 (constant specific to this test)

E: the Young's modulus of the chemically strengthened glass (unit: [MPa])

t: the average sheet thickness of the chemically strengthened glass (unit: [mm])

σ=bending stress (unit: [MPa])

As apparent from formula (2), the narrower the distance D (D>2×t) is, the larger the tensile stress σ is.

In the case where a crack is not formed in the chemically strengthened glass 2, the operator manually actuates the adjustment unit 30, and the distance D between the supporting surface 14a of the first support board 14 and the supporting surface 16a of the second support board 16, which are parallel to each other, is narrowed. Consequently, a higher tensile stress than the previous time is generated in the chemically strengthened glass 2 caused to form a curvature between the first support board 14 and the second support board 16.

Subsequently, the operator actuates the displacement unit 20 under the control of a controller and while maintaining the distance D, the position of the second support board 16 relative to the first support board 14 is displaced to examine whether a crack is formed or not in the chemically strengthened glass 2 caused to form a curvature between the first support board 14 and the second support board 16. The distance D is narrowed in a stepwise manner until a crack is formed in the chemically strengthened glass 2, and the tensile stress σ applied to the chemically strengthened glass 2 is thereby strengthened step by step to determine the braking strength of the chemically strengthened glass 2. The tensile stress σ when the chemically strengthened glass 2 is broken is employed as the breaking strength.

The chemically strengthened glass according to one embodiment of the present invention is a chemically strengthened glass including a first main surface, a second main surface facing the first main surface, and an end surface connecting the first main surface and the second main surface, wherein a compressive stress layer is provided in the first main surface and the second main surface, the average sheet thickness t is from 0.06 to 0.25 mm, and when the following bending test method is performed, the breaking strength is larger than 200 MPa.

### (Bending Test Method)

In a bending test method of disposing a first support board and a second support board in parallel so that the supporting surface of the first support board and the supporting surface of the second support board are opposed to each other,

arranging end parts of the chemically strengthened glass to be supported respectively by the first support board and the second support board,

while maintaining the distance between the supporting surface of the first support board and the supporting surface of the second support board, displacing the position of the second support board relative to the first support board by 200 mm in the direction that is parallel to the supporting surface of the first support board and the supporting surface of the second support board and that does not change the curvature direction of the chemically strengthened glass,

examining whether a crack is formed or not in the chemically strengthened glass curved between the first support board and the second support board,

in the case where a crack is not formed in the sheet material, narrowing the distance,

while maintaining the distance between the supporting surface of the first support board and the supporting surface of the second support board, displacing the position of the second support board relative to the first support board by 200 mm in the direction that is parallel to the supporting surface of the first support board and the supporting surface of the second support board and that does not change the curvature direction of the chemically strengthened glass, and

examining whether a crack is formed or not in the chemically strengthened glass curved between the first support board and the second support board,

the bending test method is performed under the conditions of the following formula (2), and the bending stress when a crack is formed in the chemically strengthened glass is taken as the breaking strength of the chemically strengthened glass.

σ=(A×E×t)/(D−t) (2)

D: the distance between the supporting surface of the first support board and the supporting surface of the second support board (unit: [mm])

A=1.198

E: the Young's modulus of the chemically strengthened glass (unit: [MPa])

t: the average sheet thickness of the chemically strengthened glass (unit: [mm])

σ=bending stress (unit: [MPa])

In the chemically strengthened glass of this embodiment, the breaking strength by the bending test method above is preferably larger than 250 MPa, more preferably larger than 300 MPa, still more preferably larger than 350 MPa, yet still more preferably 400 MPa or more. As the breaking strength is larger, the flexibility is more excellent.

### (Profiling)

The average sheet thickness t of the chemically strengthened glass of this embodiment is from 0.06 to 0.25 mm. When the average sheet thickness t is 0.06 mm or more, a compressive stress layer can be provided in the main surface of the glass so as to prevent an excessive increase in the later-described internal tensile stress CT. When the average sheet thickness t is 0.25 mm or less, high flexibility (flexible property) can be imparted to the glass. The average sheet thickness t is preferably 0.08 mm or more, more preferably 0.10 mm or more, still more preferably 0.12 mm or more. The average sheet thickness t is preferably 0.23 mm or less, more preferably 0.21 mm or less, still more preferably 0.19 mm or less. Here, the average sheet thickness t can be measured by a micrometer. The sheet thickness of the chemically strengthened glass is the distance between the first main surface and the second main surface.

The chemically strengthened glass of this embodiment includes a first main surface, a second main surface opposite to the first main surface, and an end surface connecting the first main surface and the second main surface. The first main surface and the second main surface are opposed to each other in the sheet thickness direction of the chemically strengthened glass.

In the chemically strengthened glass of this embodiment, the end surface of the chemically strengthened glass preferably includes a first inclined part tilting and extending to the second main surface side relative to the first main surface, a second inclined part tilting and extending to the first main surface side relative to the second main surface, and a curved surface part connecting the first inclined part and the second inclined part. When the end surface of the chemically strengthened glass has such a shape, cracking attributable to a crack in the end surface is suppressed, and the breaking strength a when a crack is formed by the bending test method in this embodiment can be increased. This embodiment is described in greater detail by referring to FIG. 2.

FIG. 2 shows a cross-sectional view of the chemically strengthened glass according to this embodiment. The chemically strengthened glass 100 includes a first main surface 101 and a second main surface 102 opposed to each other in the sheet thickness direction and further includes an end surface 103 connecting the first main surface and the second main surface. The end surface 103 of the chemically strengthened glass 100 includes a first inclined part 111 tilting at an angle θ₁ and extending to the second main surface 102 side relative to the first main surface 101, a second inclined part 112 tilting at an angle θ₂ and extending to the first main surface 101 side relative to the second main surface 102, and a curved surface part 113 connecting the first inclined part 111 and the second inclined part 112.

In the chemically strengthened glass 100 of this embodiment, from the viewpoint of increasing the breaking strength σ, each of the angle θ₁ between the plane including the first inclined part 111 and the first main surface 101 and the angle θ₂ between the plane including the second inclined part 112 and the second main surface 102 is preferably from 20 to 55°, more preferably from 23 to 50°, still more preferably from 24 to 40°. The angle θ₁ and the angle θ₂ may be the same or different. When θ₁=θ₂, the breaking strength σ can be increased equally in both surfaces. When θ₁<θ₂, the breaking strength σ measured particularly in the state of the first main surface being in contact with the supporting surface 14a of the first support board 14 and the supporting surface 16a of the second support board 16 can be increased.

The end surface having the shape above can be formed, for example, by performing the following chamfering on the glass before applying a chemical strengthening treatment or on the chemically strengthened glass. For the later-described reason, a compressive stress layer is preferably formed also in the end surface of the chemically strengthened glass. That is, the chemically strengthened glass is preferably manufactured by applying a chemical strengthening treatment to the glass with an end surface having the shape above. Accordingly, in the following, the case of performing chamfering on the glass before applying a chemical strengthening treatment is described.

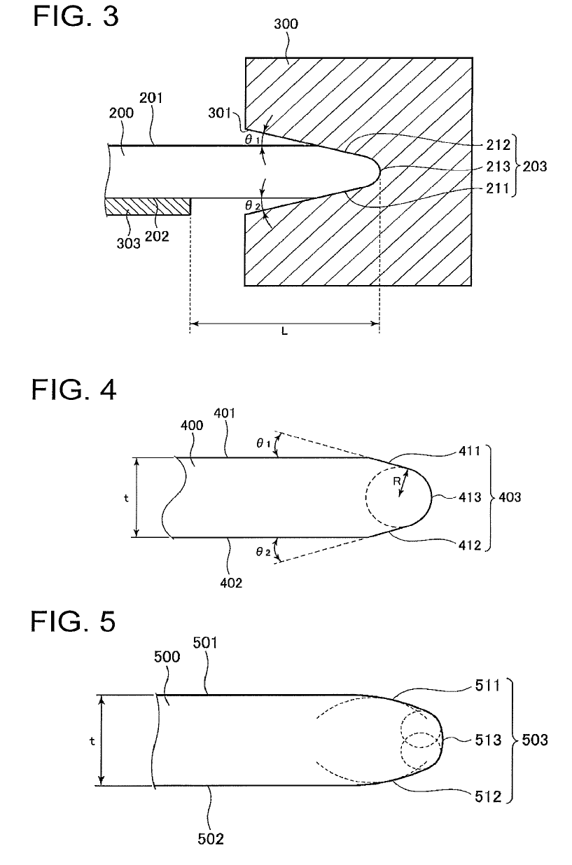

FIG. 3 illustrates how to perform chamfering for manufacturing the glass 200 of this embodiment. As illustrated in FIG. 3, the grindstone 300 has a grinding groove 301 of a shape corresponding to the shape desirable to the end surface 203 of the glass 200, and chamfering is performed by grinding the end part of the glass 200 while abutting it against the grinding groove 301 of the grindstone 300. When the chamfering is performed in this way, the glass 200 including a first main surface 201 and a second main surface 202 opposed to each other in the sheet thickness direction and further including an end surface 203 connecting the first main surface and the second main surface can be manufactured. Here, the end surface 203 of the glass 200 includes a first inclined part 211 tilting at an angle θ₁ and extending to the second main surface 202 side relative to the first main surface 201, a second inclined part 212 tilting at an angle θ₂ and extending to the first main surface 201 side relative to the second main surface 202, and a curved surface part 213 connecting the first inclined part 211 and the second inclined part 212. When this glass 200 is subjected to a chemical strengthening treatment, a chemically strengthened glass 100 having a shape illustrated in FIG. 2, with a compressive stress layer being formed in all of the first main surface 101, the second main surface 102 and the end surface 103, can be manufactured.

At the time of chamfering of the glass 200, since the glass 200 has high flexibility, the chamfering is preferably conducted by fixing the first main surface 201 or the second main surface 202 to a stage 303. By fixing the surface to the stage 303, the glass 200 can be abutted in a proper position of the grindstone 300, and the angle θ₁ and the angle θ₂ can be made to fall in the proper range. The chamfering is preferably performed while keeping a length for which the glass 200 protrudes from the stage 303, i.e., a distance L from the end part of the stage 303 to the end part of the glass 200 to be 100 mm or less. When the surface is fixed to the stage and the length for which the glass 200 protrudes from the stage 303 is set to be 100 mm or less, the glass 200 remains unswung at the time of chamfering, and a strength deterioration factor such as chipping can be eliminated. The distance L is more preferably 80 mm or less, still more preferably 60 mm or less. When the distance L is too small, the stage may come into contact with the grindstone and in addition, it becomes difficult for the grinding fluid (coolant) supplied to the grindstone 300 and the glass 200 to be appropriately supplied to the main surface side abutting the stage 303. For this reason, the distance L from the end part of the stage 303 to the end part of the glass 200 is preferably 10 mm or more.

In the cross-sectional shape in the sheet thickness direction of the chemically strengthened glass 100 of this embodiment, the curved surface part 113 in the end surface 103 has a shape curved convexly toward the direction of protruding from the chemically strengthened glass 100. Here, from the viewpoint of preventing the strength deterioration by breakage at the time of, for example, transportation of the glass, the cross-sectional shape of the curved surface part 113 is preferably an arc shape.

FIG. 4 illustrates a cross-sectional view of the chemically strengthened glass where the cross-sectional shape of the curved surface part in the end surface is an arc shape. The chemically strengthened glass 400 of this embodiment includes a first main surface 401 and a second main surface 402 opposed to each other in the sheet thickness direction and further includes an end surface 403 connecting the first main surface and the second main surface. The end surface 403 of the glass 400 includes a first inclined part 411 tilting at an angle θ₁ and extending to the second main surface 402 side relative to the first main surface 401, a second inclined part 412 tilting at an angle θ₂ and extending to the first main surface 401 side relative to the second main surface 402, and a curved surface part 413 connecting the first inclined part 411 and the second inclined part 412. The cross-sectional shape of the curved surface part 413 is an arc shape. In this embodiment, assuming that the radius of curvature of the curved surface part 413 is R, the average sheet thickness t of the chemically strengthened glass 100 and the radius of curvature R of the curved surface part 413 satisfy the relationship of t>2R.

In the chemically strengthened glass of this embodiment, assuming that the minimum radius of curvature of the curves surface part is R, the average sheet thickness t of the chemically strengthened glass and the minimum radius of curvature R of the curved surface part preferably satisfy the relationship of t≧2R. When t and R satisfy this relationship, cracking originating in a crack of the end surface can be advantageously prevented while realizing a small average sheet thickness. The minimum radius of curvature R of the curved surface part is preferably 0.125 mm or less, more preferably 0.1 mm or less, still more preferably 0.08 mm or less.

FIG. 5 illustrates a cross-sectional view of the chemically strengthened glass having another end surface shape of this embodiment. In FIG. 5, the chemically strengthened glass 500 includes a first main surface 501 and a second main surface 502. Here, as illustrated in FIG. 5, the first inclined part 511 and the second inclined part 512 of the chemically strengthened glass 500 may have an arc shape. As illustrated in FIG. 5, the cross-sectional shape of the curved surface part 513 in the end surface 503 may be expressed not in a single arc but in a plurality of arcs. However, an arc of 0.005 mm or less is not regarded as an arc and in the case where the outer shape is expressed in an arc larger than that, the minimum radius of curvature R of the curved surface part is preferably 0.125 mm or less, more preferably 0.1 mm or less, still more preferably 0.08 mm or less.

In the chemically strengthened glass of this embodiment, an arc shape may also be formed as the end surface shape by processing the end surface by means of a grindstone and then melting the glass with a chemical such as hydrogen fluoride (HF).

### (Chemical Strengthening)

In the chemically strengthened glass of this embodiment, a compressive stress layer by the ion exchange method is provided at least in the first main surface and the second main surface. In the ion exchange method, the surface of the glass is ion-exchanged to form a surface layer where a compressive stress remains. Specifically, an alkali metal ion having a small ion radius (typically, Li ion or Na ion) in a glass sheet surface is exchanged with an alkali ion having a larger ion radius (typically, Na ion or K ion for the Li ion, and K ion for the Na ion) by ion exchange at a temperature not more than the glass transition temperature. Consequently, a compressive stress remains in the glass surface, and the strength of the glass is enhanced.

In the chemically strengthened glass of this embodiment, the surface compressive stress (CS) of the first main surface and the second main surface is preferably 400 MPa or more, since generation of a crack in the main surface can be suppressed. The CS of the first main surface and the second main surface is more preferably 450 MPa or more, still more preferably 500 MPa or more. The CS of the first main surface and the second main surface is preferably 1,000 MPa or less, since an excessive increase in the later-described internal tensile stress CT can be prevented. The CS of the first main surface and the second main surface is more preferably 900 MPa or less, still more preferably 700 MPa or less. The CS of the first main surface and the second main surface can be appropriately adjusted by controlling the chemical strengthening conditions, glass composition, etc.

In the chemically strengthened glass of this embodiment, the depth of compressive stress layer (DOL) of the first main surface and the second main surface is preferably 6 μm or more, since a fine crack generated, which cannot be prevented by a surface compressive stress, is less likely to reach the internal tensile stress layer. The DOL of the first main surface and the second main surface is more preferably 8 μm or more, still more preferably 10 μm or more, yet still more preferably 12 μm or more. The DOL of the first main surface and the second main surface is preferably 25 μm or less, since an excessive increase in the later-described internal tensile stress CT can be prevented. The DOL of the first main surface and the second main surface is more preferably 20 μm or less, still more preferably 18 μm or less. The DOL of the first main surface and the second main surface can be appropriately adjusted by controlling the chemical strengthening conditions, glass composition, etc.

In the chemically strengthened glass of this embodiment, the internal tensile stress (CT) is preferably 250 MPa or less, since the glass can be prevented from breaking into pieces. The CT is more preferably 200 MPa or less, still more preferably 150 MPa or less, yet still more preferably 100 MPa or less, even yet still more preferably 50 MPa or less. In general, assuming that the glass thickness is t, the CT can be determined approximately according to the relational expression: CT=(CS×DOL)/(t−2×DOL). Here, the unit of CT and CS is MPa, and the unit of t and DOL is μm.

In the chemically strengthened glass of this embodiment, a compressive stress layer is preferably formed also in the end surface, in addition to in the first main surface and the second main surface. For example, a rectangular chemically strengthened glass has four end surfaces each connecting the first main surface and the second main surface, and a compressive stress layer is preferably formed in all the end surfaces. When a compressive stress layer is formed in all the surfaces of the chemically strengthened glass in this way, generation of a crack in the main surface and end surface can be suppressed.

In the chemically strengthened glass of this embodiment, in order not to create a breakable region within the main surface by reducing the distribution of tensile stress generated within the main surface when the glass is bent, the difference between the maximum value and the minimum value of the sheet thickness within the main surface of the chemically strengthened glass is preferably 0.03 mm or less, more preferably 0.02 mm or less, still more preferably 0.015 mm or less, yet still more preferably 0.005 mm or less.

In the chemically strengthened glass of this embodiment, in order not to create a breakable region within the main surface by reducing the distribution of tensile stress generated within the main surface when the glass is bent, the difference between the maximum value and the minimum value of CT within the main surface of the chemically strengthened glass is preferably 5 MPa or less, more preferably 3 MPa or less, still more preferably 2 MPa or less, yet still more preferably 1 MPa or less.

The shape of the chemically strengthened glass of this embodiment is, for example, a rectangular shape but is not limited thereto. The size of the chemically strengthened glass of this embodiment is not particularly limited as long as it can be applied to the above-described bending test method, but an area of the first main surface is preferably 30,000 mm² or more. The chemically strengthened glass having the area of the first main surface of 30,000 mm² or more can be used for the roll-to-roll process, and the effects of the chemically strengthened glass of this embodiment are most remarkably achieved. As an example, when the chemically strengthened glass is rectangular, the length of the long side is, for example, from 200 to 15,000 mm, and the length of the short side is, for example, from 100 to 12,000 mm.

Subsequently, the glass for use in the chemically strengthened glass of this embodiment is described. The glass used in this embodiment is not particularly limited as long as it allows for ion exchange, and for example, the glass used may be appropriately selected from soda lime glass, aluminosilicate glass, borosilicate glass, aluminoborosilicate glass, etc. Among these, in order not to cause an excessive increase in DOL of the first main surface and the second main surface, soda lime glass and soda silicate glass are preferred.

In the following, a preferable composition of soda lime glass that is one example of the glass used for the chemically strengthened glass of this embodiment, is described.

The soda lime glass used for the chemically strengthened glass of this embodiment is preferably a glass containing, for example, as a composition represented by mol %, from 60 to 75% of SiO₂, from 0.8 to 4.5% of Al₂O₃, from 10 to 19% of Na₂O, and from 0.1 to 15% of CaO.

The composition of the soda lime glass used for the chemically strengthened glass of this embodiment is not particularly limited, but includes, for example, the following glass compositions.

(i) A glass having a composition containing, as represented by mass % based on oxides, from 65 to 75% of SiO₂, from 0.1 to 8.6% of Al₂O₃, from 2 to 10% of MgO, from 1 to 10% of CaO, from 0 to 3% of SrO, from 0 to 3% of BaO, from 10 to 18% of Na₂O, from 0 to 8% of K₂O, and from 0 to 4% of ZrO₂, with Na₂O+K₂O being from 10 to 18%.

(ii) A glass having a composition containing, as represented by mass % based on oxides, from 65 to 72% of SiO₂, from 3.4 to 8.6% of Al₂O₃, from 3.3 to 6% of MgO, from 6.5 to 9% of CaO, from 13 to 16% of Na₂O, from 0 to 1% of K₂O, from 0 to 0.2% of TiO₂, from 0.005 to 0.15% of Fe₂O₃, and from 0.02 to 0.4% of SO₃, with (Na₂O+K₂O)/Al₂O₃ being from 1.8 to 5.0.

(iii) A glass having a composition containing, as represented by mol % based on oxides, from 65 to 72% of SiO₂, from 0.8 to 4.5% of Al₂O₃, from 5 to 13.5% of MgO, from 0.8 to 9% of CaO, from 12 to 17% of Na₂O, and from 0 to 3% of K₂O, with RO/(RO+R₂O) being from 0.410 to 0.52 (wherein RO represents an alkaline earth metal oxide, and R₂O represents an alkali metal oxide).

The composition of the aluminosilicate glass used for the chemically strengthened glass of this embodiment is not particularly limited, but includes, for example, the following glass compositions.

(iv) A glass having a composition containing, as represented by mol % based on oxides, from 50 to 80% of SiO₂, from 2 to 25% of Al₂O₃, from 0 to 10% of Li₂O, from 0 to 18% of Na₂O, from 0 to 10% of K₂O, from 0 to 15% of MgO, from 0 to 5% of CaO, and from 0 to 5% of ZrO₂.

(v) A glass having a composition containing, as represented by mol % based on oxides, from 50 to 74% of SiO₂, from 1 to 10% of Al₂O₃, from 6 to 14% of Na₂O, from 0.1 to 11% of K₂O, from 2 to 15% of MgO, from 0 to 6% of CaO, and from 0 to 5% of ZrO₂, in which the total of SiO₂ and Al₂O₃ contents is 75% or less, the total of Na₂O and K₂O contents is from 12 to 25%, and the total of MgO and CaO contents is from 7 to 15%.

(vi) A glass having a composition containing, as represented by mol % based on oxides, from 60 to 70% of SiO₂, from 2 to 8% of Al₂O₃, from 5 to 18% of Na₂O, from 0 to 1% of K₂O, from 4 to 15% of MgO, and from 0 to 2% of ZrO₂.

One preferred embodiment of the content of each component is described below in mass % based on oxides.

SiO₂ is a component constituting the network of the glass and is essential. This is also a component reducing generation of a crack when a flaw (indentation) is formed in the glass surface, or reducing the fracture rate when an indentation is formed after chemical strengthening. When the content of SiO₂ is 50% or more, reduction in the stability, acid resistance, weather resistance or chipping resistance of the glass can thereby be avoided. The content of SiO₂ is preferably 60% or more, more preferably 65% or more, still more preferably 66% or more. On the other hand, when the content of SiO₂ is 80% or less, reduction of the meltability due to an increase in the viscosity of the glass can thereby be avoided. The content of SiO₂ is preferably 75% or less, more preferably 72% or less.

Al₂O₃ is not an essential component but is a component effective for enhancing ion-exchange performance and chipping resistance and also is a component increasing the surface compressive stress. The content of Al₂O₃ is preferably 0.1% or more, more preferably 2% or more, still more preferably 3.4% or more. On the other hand, when the content of Al₂O₃ is 12% or less, reduction of the meltability due to an increase in the viscosity of the glass can thereby be avoided. The content of Al₂O₃ is preferably 10% or less, more preferably 8.6% or less.

Na₂O is a component forming a surface compressive stress layer by ion exchange and enhancing the meltability of the glass and is essential. When the content of Na₂O is 10% or more, a desired surface compressive stress layer can thereby be formed by ion exchange. The content is preferably 11% or more, more preferably 12% or more, still more preferably 13% or more. On the other hand, when the content of Na₂O is 19% or less, reduction of the weather resistance or acid resistance or generation of a crack from indentation can thereby be avoided. The content of Na₂O is preferably 18% or less, more preferably 16% or less, still more preferably 15% or less.

CaO is a component enhancing the meltability of the glass and is preferably contained. When the content of CaO is 0.1% or more, the meltability can thereby be enhanced. The content is preferably 1% or more, more preferably 4% or more, still more preferably 6.5% or more. On the other hand, when the content of CaO is 15% or less, the depth of the surface compressive stress layer can thereby be increased. The content of CaO is preferably 10% or less, more preferably 9% or less, still more preferably 5% or less.

Fe₂O₃ is a component enhancing the meltability of the glass and is preferably contained. Usually, Fe₂O₃ in glass brings about absorption of visible light and is unfavorable, but in the case where the sheet thickness is small, the absorption of light decreases and is therefore less likely to raise a problem. The content of Fe₂O₃ is preferably 0.005% or more, more preferably 0.01% or more, still more preferably 0.03% or more, yet still more preferably 0.06% or more. On the other hand, when this component is contained excessively, the color attributed to Fe₂O₃ becomes a problem, and the content of Fe₂O₃ is therefore preferably less than 0.2%, more preferably less than 0.15%, still more preferably less than 0.12%, yet still more preferably less than 0.095%.

The Young's modulus of the chemically strengthened glass of this embodiment may vary depending on the glass composition, etc. but is, for example, from 65 to 80 MPa. The Young's modulus (E) of the chemically strengthened glass can be measured by the ultrasonic pulse method.

The chemically strengthened glass of this embodiment can be produced as follows, for example. First, a glass for use in the later-described chemical strengthening is prepared. For example, raw materials of respective components of the glass are mixed and heated and melted in a glass melting furnace. The glass is then homogenized by bubbling, stirring, addition of a refining agent, etc., formed into a glass sheet having a predetermined thickness by a conventionally known forming method, and slowly cooled.

Examples of the glass forming method includes a float method, a press method, a fusion method, and a down-draw method. Among these, a float method suitable for mass production is preferred. A continuous forming method other than the float method, i.e., a fusion method and a down-draw method, are also preferred.

Thereafter, the formed glass is subjected to, if desired, grinding and polishing treatments to form a glass substrate. In the case of cutting the glass substrate into desired shape and size or chamfering the glass substrate, cutting or chamfering of the glass substrate is preferably performed before applying the later-described chemical strengthening treatment, because a compressive stress layer is formed also on the end surface by the subsequent chemical strengthening treatment.

The glass substrate formed is subjected to a chemical strengthening treatment, then washed and dried, whereby the chemically strengthened glass of this embodiment can be produced.

The chemical strengthening treatment can be performed by a conventionally known method. In the chemical strengthening treatment, a glass sheet is put into contact, by immersion, etc., with a melt of a metal salt (for example, potassium nitrate) containing a metal ion having a large ion radius (typically, K ion), and a metal ion having a small ion radius (typically, Na ion or Li ion) in the glass sheet is thereby exchanged with the metal ion having a large ion radius.

The chemical strengthening treatment (ion exchange treatment) is not particularly limited but may be performed, for example, by immersing a glass sheet in a molten salt, such as potassium nitrate, heated at 300 to 550° C. for 5 minutes to 20 hours. The heating temperature of the molten salt is preferably from 300 to 450° C., and the immersing time of the glass sheet in the molten salt is preferably from 0.1 to 15 hours.

Examples of the molten salt for performing the chemical strengthening treatment includes an alkali sulfate and an alkali chloride salt, such as potassium nitrate, sodium sulfate, potassium sulfate, sodium chloride and potassium chloride. One of these molten salts may be used alone, or a plurality of kinds thereof may be used in combination.

In this embodiment, the treatment conditions of the chemical strengthening treatment are not particularly limited, and optimum conditions may be selected by taking into account the properties and composition of the glass, the kind of the molten salt, and the chemical-strengthening properties desirable to the finally obtained chemical strength glass, such as surface compressive stress (CS) and depth of compressive stress layer (DOL).

The chemically strengthened glass of this embodiment has a small sheet thickness and abundant flexibility and can therefore be used in a curved state. For example, the chemically strengthened glass of this embodiment may be used in a state of the radius of curvature being 15,000 mm or more. The “chemically strengthened glass where the radius of curvature is 15,000 mm or more” as used herein indicates that when the first and second main surfaces of the chemically strengthened glass are a convex surface and a concave surface, respectively, or the first and second main surfaces are a concave surface and a convex surface, respectively, the radius of curvature of a slight curve observed is 15,000 mm or more.

In the chemically strengthened glass of this embodiment, the strength is enhanced by chemical strengthening. In addition, since the average sheet thickness is small and a crack is not formed in the above-described bending test method, the flexibility is excellent. More specifically, the chemically strengthened glass of this embodiment is a glass having a large area and exhibiting excellent flexibility and excellent strength. Accordingly, the chemically strengthened glass of this embodiment can be suitably used for applications where the glass needs to be bent in the course of operation or must not be easily broken when bent, for example, an application such as photomask substrate, LCD image mask substrate, cold bending, flexible substrate for organic EL, cover glass for lighting, glass for inkjet printing, and glass substrate for solar cell.

The chemically strengthened glass of this embodiment may be used as it is but may also be used as a laminate, if desired, by stacking it with another layer such as resin layer and fixing the stack in the bent state.

In some suitable applications, a functional material is preferably provided on the chemically strengthened glass of this embodiment. For example, in the case of using the chemically strengthened glass of this embodiment as a photomask substrate or an LCD image mask substrate, a photosensitizer is preferably provided on the chemically strengthened glass of this embodiment.

In the case of using the chemically strengthened glass of this embodiment for cold bending, the glass is preferably used as a glass member in which at least two sheets of the chemically strengthened glass of this embodiment are stacked. It is more preferable to stack at least two sheets of the chemical strengthened glass of this embodiment by interposing a resin layer therebetween.

In the case of using the glass as a flexible substrate for organic EL, a cover glass for lighting, or a glass for inkjet printing, a treatment for increasing the specific surface area of the chemically strengthened glass of this embodiment is preferably performed. For example, the glass is preferably used as a glass member by applying sol-gel coating or etching treatment to at least one surface of the chemically strengthened glass to provide a layer containing an organic material as the main component on the surface.

The chemically strengthened glass of this embodiment may be used as a glass substrate for solar cell. In the case of using the chemically strengthened glass of this embodiment as a glass substrate for solar cell, specific effects such as high light transmittance, high heat resistance, thermal expansion coefficient matched to a chemical material, and high efficiency due to a component contained in the glass, compared with other materials such as polymer, are achieved. Furthermore, application to a conventional solar cell module structure of super straight type is also possible.

The chemically strengthened glass of this embodiment is preferably used, among others, as a cover glass substrate for a flexible thin-film solar cell. In the case of using the glass as a cover glass substrate for a thin-film solar cell, it is preferred that the average sheet thickness t is 0.25 mm or less and the content of Al₂O₃ is 3 mass % or more. With an average sheet thickness t of 0.25 mm or less, the light energy absorbed by the glass can be reduced, and with an Al₂O₃ content of 3 mass % or more, the conversion efficiency of the thin-film solar cell can be enhanced.

In a flexible thin-film solar cell module having the chemically strengthened glass of this embodiment, a photoelectric conversion layer is provided on the chemically strengthened glass. The thickness of the photoelectric conversion layer is preferably 100 μm or less, and the material of the photoelectric conversion layer is preferably CdTe. In the flexible thin-film solar cell module, it is preferred that a crack originating in at least one main surface of a first main surface and a second main surface opposite to the first main surface of the chemically strengthened glass is not formed in the bending test method performed under the conditions of formula (1). In this case, the bending test apparatus 10 curve the flexible thin-film solar cell module instead of the chemically strengthened glass.

### EXAMPLES

The present invention is described below by referring to Examples, but the present invention is not limited thereto.

### Example 1

A glass sheet having a composition as represented by mass percentage based on oxides shown in Table 1 was manufactured. Silica sand, soda ash, dolomite, feldspar, aluminum oxide, calcium carbonate, magnesium carbonate, and salt cake were used as glass raw materials and melted, and the melt was formed into a glass ribbon having a thickness of about 0.33 mm in a float bath. The composition in Table 1 is an analysis value by X-ray fluorescence analysis when the main surface of each glass was polished 100 μm and measured.

The obtained glass sheet was cut into a size of 300 mm×200 mm and then subjected to a predetermined edge processing by using a grindstone of #800 such that the end surface shape becomes the shape illustrated in FIG. 4 (θ₁: 27°, θ₂: 27°, R: 0.12 mm). Thereafter, the glass sheet was etched using an HF solution to reduce the sheet thickness. In the obtained glass sheet, the size of the first main surface and the second main surface was 300 mm (long side)×200 mm (short side), and the average sheet thickness was 0.215 mm.

Subsequently, ion exchange by immersing the manufactured glass sheet in molten potassium salt at a temperature of 425° C., having a KNO₃ content ratio of 99.5 mass % and a NaNO₃ content ratio of 0.5 mass %, for 670 minutes was performed to obtain the chemically strengthened glass of Example 1.

### <Measurement of Bending Strength>

The obtained chemically strengthened glass was measured for the bending strength by performing the following bending test method by use of the bending test apparatus illustrated in FIG. 1. The results are shown in Table 1.

### (Bending Test Method)

In a bending test method of disposing a first support board and a second support board in parallel so that the supporting surface of the first support board and the supporting surface of the second support board are opposed to each other,

arranging end parts of the chemically strengthened glass to be supported respectively by the first support board and the second support board,

while maintaining the distance between the supporting surface of the first support board and the supporting surface of the second support board, displacing the position of the second support board relative to the first support board by 200 mm in the direction that is parallel to the supporting surface of the first support board and the supporting surface of the second support board and that does not change the curvature direction of the chemically strengthened glass,

examining whether a crack is formed or not in the chemically strengthened glass curved between the first support board and the second support board,

in the case where a crack is not formed in the sheet material, narrowing the distance,

while maintaining the distance between the supporting surface of the first support board and the supporting surface of the second support board, displacing the position of the second support board relative to the first support board by 200 mm in the direction that is parallel to the supporting surface of the first support board and the supporting surface of the second support board and that does not change the curvature direction of the chemically strengthened glass, and

examining whether a crack is formed or not in the chemically strengthened glass curved between the first support board and the second support board,

the bending test method is performed under the conditions of the following formula (2), and the bending stress when a crack is formed in the chemically strengthened glass is taken as the breaking strength of the chemically strengthened glass.

σ=(A×E×t)/(D−t) (2)

D: the distance between the supporting surface of the first support board and the supporting surface of the second support board (unit: [mm])

A=1.198

E: the Young's modulus of the chemically strengthened glass (unit: [MPa])

t: the average sheet thickness of the chemically strengthened glass (unit: [mm])

σ=bending stress (unit: [MPa])

The breaking strength was determined on 21 sheets of the chemically strengthened glass by the method above, and an average value (average breaking strength) was calculated. The results obtained are shown in Table 1.

### <Measurement or Calculation of CS, DOL and CT>

The obtained chemically strengthened glass was measured for the surface compressive stress CS (unit: MPa) and the depth of compressive stress layer DOL (unit: μm). CS and DOL were measured by means of a surface stress meter, FSM-6000, manufactured by Orihara Industrial Co., Ltd.

The internal tensile stress CT (unit: MPa) of the chemically strengthened glass was determined from the surface compressive stress CS (unit: MPa), the depth of compressive stress layer DOL (unit: mm) and the average sheet thickness t (unit: mm) of the glass based on the following formula.

CT=CS [MPa]*DOL [mm]/(t [mm]−2*DOL [mm])

The measurement or calculation results of CS, DOL and CT are shown in Table 1.

### Example 2

A float glass sheet having a thickness of about 0.33 mm and having a composition as represented by mass percentage based on oxides shown in Table 1, manufactured in the same manner as in Example 1, was cut into a size of 650 mm×550 mm and subjected to predetermined chamfering by using a grindstone of #600. Thereafter, the glass sheet was etched using an HF solution to reduce the sheet thickness. Furthermore, the glass sheet was cut into a size of about 500 mm×400 mm, and the end surface of the glass sheet was subjected to predetermined chamfering by using a grindstone of #800 such that the end surface shape becomes the shape illustrated in FIG. 4 (θ₁: 26°, θ₂: 26°, R: 0.10 mm). In the obtained glass sheet, the size of the first main surface and the second main surface was 500 mm (long side)×400 mm (short side), and the average sheet thickness was 0.15 mm.

Subsequently, ion exchange by immersing the manufactured glass sheet in molten potassium salt at a temperature of 425° C., having a KNO₃ content ratio of 99.5 mass % and a NaNO₃ content ratio of 0.5 mass %, for 300 minutes was performed to obtain the chemically strengthened glass of Example 2. The average value (average breaking strength) of the breaking strength measured by performing the bending test on 18 sheets of the obtained chemically strengthened glass, CS, DOL and CT are shown in Table 1.

### Example 3

A float glass sheet having a thickness of about 0.33 mm and having a composition as represented by mass percentage based on oxides shown in Table 1, manufactured in the same manner as in Example 1, was cut into a size of 650 mm×550 mm and subjected to predetermined chamfering by using a grindstone of #600. Thereafter, the glass sheet was etched using an HF solution to reduce the sheet thickness. Furthermore, the glass sheet was cut into a size of about 500 mm×400 mm and subjected to predetermined chamfering such that the end surface shape becomes the shape illustrated in FIG. 4 (θ₁: 26°, θ₂: 26°, R: 0.10 mm). In the obtained glass sheet, the size of the first main surface and the second main surface was 500 mm (long side)×400 mm (short side), and the average sheet thickness was 0.15 mm.

Subsequently, ion exchange by immersing the manufactured glass sheet in molten potassium salt at a temperature of 430° C., having a KNO₃ content ratio of 99.3 mass % and a NaNO₃ content ratio of 0.7 mass %, for 350 minutes was performed to obtain the chemically strengthened glass of Example 3. CS, DOL and CT of this chemically strengthened glass are shown in Table 1. With respect to the obtained chemically strengthened glass, the bending test method was performed using the bending test apparatus illustrated in FIG. 1, and it could be confirmed that the glass sheet is not broken up to a curvature of D=50 mm. This result could confirm that the breaking stress is 260 MPa or more.

### Example 4

A float glass sheet having a thickness of about 0.33 mm and having a composition as represented by mass percentage based on oxides shown in Table 1, manufactured in the same manner as in Example 1, was cut into a size of 650 mm×550 mm and subjected to predetermined chamfering by using a grindstone of #800 such that the end surface shape becomes the shape illustrated in FIG. 4 (θ₁: 27°, θ₂: 27°, R: 0.12 mm). Thereafter, the glass sheet was etched using an HF solution to reduce the sheet thickness. In the obtained glass sheet, the size of the first main surface and the second main surface was 650 mm (long side)×550 mm (short side), and the average sheet thickness was 0.11 mm.

Subsequently, ion exchange by immersing the manufactured glass sheet in molten potassium salt at a temperature of 430° C., having a KNO₃ content ratio of 99.3 mass % and a NaNO₃ content ratio of 0.7 mass %, for 340 minutes was performed to obtain the chemically strengthened glass of Example 4. CS, DOL and CT of this chemically strengthened glass are shown in Table 1. With respect to the obtained chemically strengthened glass, the bending test method was performed using the bending test apparatus illustrated in FIG. 1, and it could be confirmed that the glass sheet is not broken up to a curvature of D=30 mm. This result could confirm that the breaking stress is 315 MPa or more.

### Example 5

A float glass sheet having a thickness of about 0.33 mm and having a composition as represented by mass percentage based on oxides shown in Table 1, manufactured in the same manner as in Example 1, was cut into a size of 650 mm×550 mm and subjected to predetermined chamfering by using a grindstone of #600. Thereafter, the glass sheet was etched using an HF solution to reduce the sheet thickness to 0.2 mm. Furthermore, the glass sheet was cut into a size of about 300 mm×210 mm and subjected to predetermined chamfering such that the end surface shape becomes the shape illustrated in FIG. 4 (θ₁: 26°, θ₂: 26°, R: 0.10 mm). The obtained glass sheet was again etched using an HF solution to reduce the sheet thickness to 0.07 mm. In the obtained glass sheet, the size of the first main surface and the second main surface was 300 mm (long side)×210 mm (short side), and the average sheet thickness was 0.07 mm.

Subsequently, ion exchange by immersing the manufactured glass sheet in molten potassium salt at a temperature of 430° C., having a KNO₃ content ratio of 99.3 mass % and a NaNO₃ content ratio of 0.7 mass %, for 300 minutes was performed to obtain the chemically strengthened glass of Example 4. CS, DOL and CT of this chemically strengthened glass are shown in Table 1. With respect to the obtained chemically strengthened glass, the bending test method was performed using the bending test apparatus illustrated in FIG. 1, and it could be confirmed that the glass sheet is not broken up to a curvature of D=20 mm. This result could confirm that the breaking stress is 303 MPa or more.

### Comparative Example 1

A raw material prepared by appropriately selecting glass raw materials used in general, such as oxide, hydroxide, carbonate or nitrate, so as to provide a glass having a composition as represented by mass percentage based on oxides shown in Table 1 and mixing these materials was put in a platinum crucible, melted at a temperature of 1,550 to 1,650° C. for 3 to 5 hours, defoamed and homogenized.

The molten glass obtained was cast into a mold material, and a glass block was obtained. This glass block was cut and ground, and the first main surface and the second main surface were mirror-finished to manufacture a glass sheet of 300 mm×300 mm×0.4 mm.

Subsequently, ion exchange by immersing the manufactured glass sheet in molten potassium salt at a temperature of 435° C., having a KNO₃ content ratio of 100 mass %, for 60 minutes was performed to obtain the chemically strengthened glass of Comparative Example 1.

With respect to the obtained chemically strengthened glass, in respective 50-mm portions on both ends out of 300 mm, a cut line (scribe line) was formed (scribed) using a scriber, SS450, manufactured by Citizen Seimitsu Co., Ltd. and a cemented carbide wheel manufactured by Mitsuboshi Diamond Industrial Co., Ltd. within the conditions of a wheel angle of 130°, an indentation load of 13 to 14 N (from 1.3 to 1.4 kgf), a depth of cut of 0.1 mm and a cutting speed of 300 mm/sec, and bend-breaking (break) was performed along the cut line (scribe line). A glass sheet of 300 mm×200 mm×0.4 mm was thereby manufactured.

The bending test method was attempted to be performed on the obtained chemically strengthened glass sheet by using the bending test apparatus illustrated in FIG. 1, but the glass sheet was broken when bent to D=200 mm. In this case, the bending stress can be determined according to formula (2). This result could confirm that the breaking strength is 144 MPa or less.

TABLE 1

| | | | | | | Comparative |
|---|---|---|---|---|---|---|
| | Example 1 | Example 2 | Example 3 | Example 4 | Example 5 | Example 1 |
| | Soda Lime | Soda Lime | Soda Lime | Soda Lime | Soda Lime | Aluminosilicate |
| | Glass | Glass | Glass | Glass | Glass | Glass |
| SiO₂ (mass %) | 72 | 68.5 | 72 | 68.5 | 68.5 | 73 |
| Al₂O₃ (mass %) | 1.86 | 5.01 | 1.86 | 5.01 | 5.01 | 7 |
| CaO (mass %) | 7.82 | 7.21 | 7.82 | 7.21 | 7.21 | 0 |
| MgO (mass %) | 4.69 | 4.12 | 4.69 | 4.12 | 4.12 | 6 |
| Na₂O (mass %) | 13 | 14.6 | 13 | 14.6 | 14.6 | 14 |
| K₂O (mass %) | 0.31 | 0.24 | 0.31 | 0.24 | 0.24 | 0 |
| TiO₂ (mass %) | 0.07 | 0.13 | 0.07 | 0.13 | 0.13 | 0 |
| Fe₂O₃ (mass %) | 0.104 | 0.08 | 0.104 | 0.08 | 0.08 | 0 |
| SO₃ (mass %) | 0.19 | 0.17 | 0.19 | 0.17 | 0.17 | 0 |
| E (MPa) | 72 | 72 | 72 | 72 | 72 | 68 |
| CS (MPa) | 550 | 630 | 490 | 600 | 590 | 750 |
| DOL (μm) | 14 | 13 | 11.5 | 15.5 | 14.5 | 17 |
| Average sheet thickness t (mm) | 0.215 | 0.175 | 0.15 | 0.110 | 0.070 | 0.4 |
| CT (MPa) | 41 | 55 | 45 | 116 | 223 | 35 |
| (Average) Breaking strength (MPa) | 463 | 421 | ≥260 | ≥315 | ≥303 | ≤144 |

While the invention has been described in detail and with reference to specific embodiments thereof, it will be apparent to one skilled in the art that various changes and modifications can be made therein without departing from the spirit and scope of the invention.

This application is based on Japanese Patent Application (Patent Application No. 2015-110899) filed on May 29, 2015, the entirety of which is incorporated herein by way of reference.

### DESCRIPTION OF REFERENCE NUMERALS AND SIGNS

2 Chemically strengthened glass
2a, 2b End part
10 Bending test apparatus
12 Base
14 First support board
14a Supporting surface
16 Second support board
16a Supporting surface
17 Stopper
20 Displacement unit
21 Ascending-descending frame
22 Motor
23 Ball screw mechanism
24 Slider block
30 Adjustment unit
40 Detection unit
50 Support unit
52 Coupling unit
60 Placement unit
100 Chemically strengthened glass
101 First main surface
102 Second main surface
103 End surface
111 First inclined part
112 Second inclined part
113 Curved surface part
200 Glass
201 First main surface
202 Second main surface
203 End surface
211 First inclined part
212 Second inclined part
213 Curved surface part
300 Grindstone
301 Grinding groove
303 Stage
400 Chemically strengthened glass
401 First main surface
402 Second main surface
403 End surface
411 First inclined part
412 Second inclined part
413 Curved surface part
500 Chemically strengthened glass
501 First main surface
502 Second main surface
503 End surface
511 First inclined part
512 Second inclined part
513 Curved surface part

1. A chemically strengthened glass comprising a first main surface, a second main surface opposite to the first main surface, and an end surface connecting the first main surface and the second main surface, wherein:
a compressive stress layer is provided in the first main surface and the second main surface;
an average sheet thickness t is from 0.06 to 0.25 mm; and
when the following bending test method is performed, a crack originating in at least one main surface of the first main surface and the second main surface is not formed:
(Bending Test Method)
a bending test method of disposing a first support board and a second support board in parallel so that a supporting surface of the first support board and a supporting surface of the second support board are opposed to each other,
arranging an end part of the chemically strengthened glass to be supported respectively by the first support board and the second support board,
while maintaining a distance between the supporting surface of the first support board and the supporting surface of the second support board at a distance D [mm] determined according to the following formula (1), displacing a position of the second support board relative to the first support board by 200 mm in a direction that is parallel to the supporting surface of the first support board and the supporting surface of the second support board and that does not change a curvature direction of the chemically strengthened glass, and
examining whether a crack is formed or not in the chemically strengthened glass curved between the first support board and the second support board, is performed:
D=(A×E×t/σ)+t (1),
D; the distance between the supporting surface of the first support board and the supporting surface of the second support board (unit [mm]),
A=1.198,
E; Young's modulus of the chemically strengthened glass (unit [MPa]),
T; the average sheet thickness of the chemically strengthened glass (unit [mm]), and
σ=200 (unit [MPa]).

2. The chemically strengthened glass according to claim 1, wherein the end surface of the chemically strengthened glass comprises a first inclined part tilting and extending to a second main surface side relative to the first main surface, a second inclined part tilting and extending to a first main surface side relative to the second main surface, and a curved surface part connecting the first inclined part and the second inclined part.

3. The chemically strengthened glass according to claim 2, wherein a cross-sectional shape of the curved surface part in a sheet thickness direction of the chemically strengthened glass is an arc shape.

4. The chemically strengthened glass according to claim 2, wherein a minimum radius of curvature of the curved surface part is 0.125 mm or less.

5. The chemically strengthened glass according to claim 1, wherein the surface compressive stress of the first main surface and the second main surface is from 400 to 1,000 MPa.

6. The chemically strengthened glass according to claim 1, wherein a depth of compressive stress layer of the first main surface and the second main surface is from 6 to 25 μm.

7. The chemically strengthened glass according to claim 1, wherein an internal tensile stress is 250 MPa or less.

8. The chemically strengthened glass according to claim 1, wherein a compressive stress layer is provided in the end surface.

9. The chemically strengthened glass according to claim 1, wherein a difference between a maximum value and a minimum value of the sheet thickness within a plane of the chemically strengthened glass is 0.03 mm or less.

10. The chemically strengthened glass according to claim 1, that contains, as represented by mol % based on oxides, from 0.8 to 4.5% of Al₂O₃.

11. The chemically strengthened glass according claim 1, that is for a photomask substrate.
